(19) United States
(12) Patent Application Publication
(10) Pub. No.: US 2004/0188811 A1
(43) Pub. Date: Sep. 30, 2004

(54) Circuit package apparatus, systems, and methods

(75) Inventors: Gilroy J. Vandentop, Tempe, AZ (US); Rajendran Nair, Gilbert, AZ (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 10/396,945

(22) Filed: Mar. 24, 2003

(51) Int. Cl. H01L 21/44

(52) U.S. Cl. 257/678; 438/106

(57) ABSTRACT

An apparatus and system, as well as methods for providing them, may include a die having a core circuit electrically coupled to a power converter included in an active substrate.

### TECHNICAL FIELD

Embodiments of the invention relate generally to apparatus, systems, and methods used to package circuitry, including processors and power converters.

### BACKGROUND INFORMATION

Processor performance scaling leads to the desire for decreased operating voltages and a resulting demand for increased supply currents from the power delivery system. Operational current surges, combined with decoupling capacitance properties, can result in power supply voltage variations referred to as supply “droops,” which may be seen as noise by the processor and interfere with proper operations. An important challenge in minimizing such droops is reducing the processor package loop inductance, which may be proportional to the inverse product of the die capacitance per unit area and the square of the operating frequency. These considerations, among others, may drive the search for new circuitry packaging techniques.

### BRIEF DESCRIPTION OF THE DRAWINGS

FIG. 1 is a side cut-away view of an apparatus and system according to various embodiments of the invention;

FIG. 2 is a side cut-away view of an apparatus and system according to various alternative embodiments of the invention;

FIG. 3 is a flow chart illustrating several methods according to various embodiments of the invention; and

FIG. 4 is a block diagram of an article according to various embodiments of the invention.

### DETAILED DESCRIPTION

In the following detailed description of various embodiments of the invention, reference is made to the accompanying drawings that form a part hereof, and in which are shown by way of illustration, and not of limitation, specific embodiments in which the subject matter may be practiced. In the drawings, like numerals describe substantially similar components throughout the several views. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. The following detailed description, therefore, is not to be taken in a limiting sense, and the scope of various embodiments of the invention is defined only by the appended claims, along with the full range of equivalents to which such claims are entitled.

Provided herein is a description of an active substrate with one or more integrated power conversion devices that can be used to reduce the interconnect impedance (including the package loop inductance) between the power conversion device and an associated core circuit, such as a processor, memory, wireless transceiver, etc. The active substrate may operate to convert a high voltage, low current power supply input to a low voltage, high current output that is fed to the core circuit(s), for example. Thus, as used herein, the term “active substrate” refers to a substrate having one or more power conversion devices wholly embedded therein. Thus, for example, an active substrate may comprise a bismaleimide triazine material having a DC-DC power converter embedded therein. Another example of an active substrate includes a copper substrate having a die embedded therein, the die including one or more power transistors.

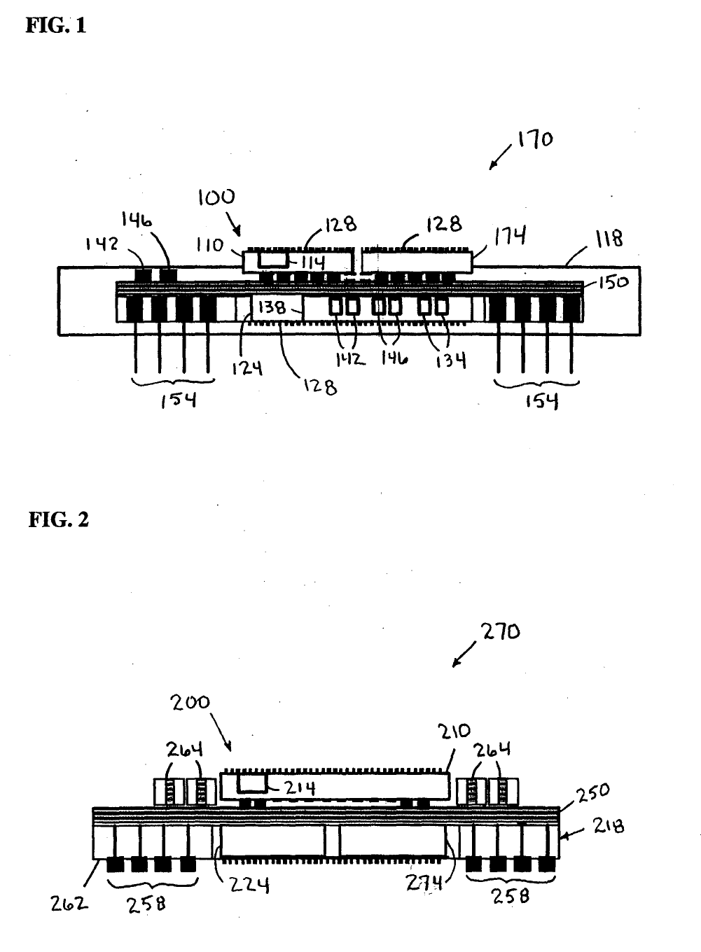

FIGS. 1 and 2 are side cut-away views of an apparatus and system according to various embodiments of the invention. The apparatus 100 may include a die 110 having one or more core circuits 114, such as a processor, a memory, a wireless transceiver, etc. The apparatus 100 may also include an active substrate 118 having a power converter 124 (e.g., a switching DC-DC converter), which may in turn be electrically coupled to the core circuit(s) 114. To assist in heat removal, thermal interface material 128 may also be included in the apparatus 100.

As seen in FIG. 1, Bump-less Build-Up Layer (BBUL) packaging may be used to embed the power converter 124 in the active substrate 118, as well as to provide interconnection and fan-out layers. For more information about BBUL packaging, please refer to “Bump-less Build-Up Layer Packaging” by Steven Towle, et. al., ASME International Mechanical Engineering Congress and Exposition, November 2001. Thus, one or more of the dice (i.e., core circuit, power converter) 114, 124 may be embedded in the active substrate 118 using a BBUL packaging process. In this manner, the thermal coefficient of expansion associated with one or more of the dice 114, 124 may be substantially matched to the thermal coefficient of expansion associated with the active substrate 118.

Power switching devices 134 may be used to construct one or more high-efficiency switching regulators 138 that can be integrated into a die 124, such as a complementary metal-oxide semiconductor (CMOS) die, embedded within the active substrate 118. A material having a coefficient of thermal expansion (CTE) matched well with that of silicon, including polycrystalline silicon, may be included in the active substrate 118, although embodiments of the invention are not so limited. Alternatively, or in addition, the active substrate 118 may include materials such as FR4 (Fire Retardant Grade 4), alloys, such as iron-nickel alloys, ceramics, and/or copper.

The active substrate 118 may-comprise any number of materials, including a flexible material. The materials included in the active substrate 118 may be non-conductive or conductive, and may provide a supporting structure and/or insulating properties for one or more core circuits 114, depending upon the configuration and requirements of the apparatus 100.

Thus, the power converter 124 may include one or more power switching devices 134, and may operate on a supply voltage so as to reduce the supply voltage and provide a reduced supply voltage to the core circuit 114. The power converter 124 may also include various components, such as power switching devices 134 (e.g., power switching transistors), inductors 142, and/or capacitors 146.

A plurality of buildup layers 150 (e.g., BBUL packaging layers) may be coupled to the active substrate 118. One or more of the buildup layers 150 may include inductors 142 of various types, including inductors 142 comprising magnetic material. Inductors 142 that include magnetic material of properties appropriate to the desired functionality can thus be integrated into the power converter 124 and/or one or more of the build-up layers. Such inductors 142 may have a small form factor, high current capability, low parasitic resistance, and high self-resonant frequency.

One or more buildup layers 150 may also include capacitors 146 of various types, including capacitors 146 having a metal-insulator-metal (MIM) structure. The capacitance needed to hold charge corresponding to the input high voltage (e.g., an input to the power converter 124) may also be integrated into a die 124 through the use of MINI capacitance structures, perhaps using MIM structures similar to or identical to those in use in dynamic read-only memory (DRAM) circuitry, as known to those of skill in the art. A possible benefit to integrating capacitance into the power converter 124 is that associated series parasitic values (i.e., resistance, inductance) may be reduced, so as to have less overall impact on power delivery to the core circuit(s) 114.

Various mechanisms for supplying power to the power converter 124 may be implemented. For example, referring to FIG. 1, it can be seen that a plurality of pins 154 may be coupled to the power converter 124. Referring to FIG. 2, a plurality of contacts 258 including conductive material, such as solder bumps, may also be coupled to the power converter 224. However, any type of contact 258 that can be used to deliver energy to the power converter may be utilized. The contacts 258 can be located on a surface 262 of the active substrate 218 and/or embedded within the substrate 218. Thus, the contacts 258 may be even be formed by etching a conductive material attached to the active substrate 218, or embedded in the substrate 218.

The active substrate 118, 218 may be configured in many different ways, including configuration as a pin-grid array (see FIG. 1) or a land-grid array (see FIG. 2). The apparatus 100, 200 may also be enhanced as exemplified in FIG. 2 to include additional devices, such as external decoupling capacitors 264 coupled to the substrate 218 and/or buildup layers 250.

Other embodiments of the invention may also be realized. For example, as shown in FIGS. 1 and 2, a system 170, 270 may comprise a wireless transceiver 174, 274, a die 110, 210, and an active substrate 118, 218. The die 110, 210 may include a core circuit 114, 214 capable of being communicatively coupled to the wireless transceiver 174, 274, and the active substrate 118, 218 may have a power converter 124, 224 electrically coupled to the core circuit 114, 214.

The wireless transceiver 174, 274 may be fabricated on a die, as may the power converter 124, 224. One or more of the dice 110, 210, 124, 224, 174, 274 (i.e., core circuit, power converter, and/or wireless transceiver) may be embedded in the active substrate 118, 218 using a BBUL packaging process. The thermal coefficient of expansion associated with one or more of the dice 110, 210, 124, 224, 174, 274 may be substantially matched to the thermal coefficient of expansion associated with the active substrate 118, 218.

The apparatus 100, 200, dice 110, 210, core circuits 114, 214, active substrate 118, 218, power converter 124, 224, thermal interface material 128, power switching devices 134, switching regulators 138, inductors 142, capacitors 146, buildup layers 150, pins 154, systems 170, 270, wireless transceivers 174, 274, contacts 258, and external decoupling capacitors 264 may all be characterized as “modules” herein. Such modules may include hardware circuitry, and/or a processor and/or memory circuits, software program modules and objects, and/or firmware, and combinations thereof, as desired by the architect of the apparatus 100, 200 and the systems 170, 270, and as appropriate for particular implementations of various embodiments of the invention. For example, such modules may be included in an operational simulation package, such as a software electrical signal simulation package, a power usage and distribution simulation package, and/or a power/heat dissipation simulation package, or a combination of software and hardware used to simulate potential circuit packaging designs and their operations.

It should also be understood that the apparatus and systems of various embodiments of the invention can be used in applications other than for power delivery to processors, and other than for systems that include processors, and thus, embodiments of the invention are not to be so limited. The illustrations of an apparatus 100, 200 and a system 170, 270 are intended to provide a general understanding of the structure of various embodiments of the invention, and they are not intended to serve as a complete description of all the elements and features of apparatus and systems that might make use of the structures described herein.

Applications which may include the novel apparatus and systems of various embodiments of the invention include electronic circuitry used in high-speed computers, communication and signal processing circuitry, data transceivers, modems, processor modules, embedded processors, and application-specific modules, including multilayer, multi-chip modules. Such apparatus and systems may further be included as sub-components within a variety of electronic systems, such as televisions, cellular telephones, personal computers, workstations, radios, video players, vehicles, and others.

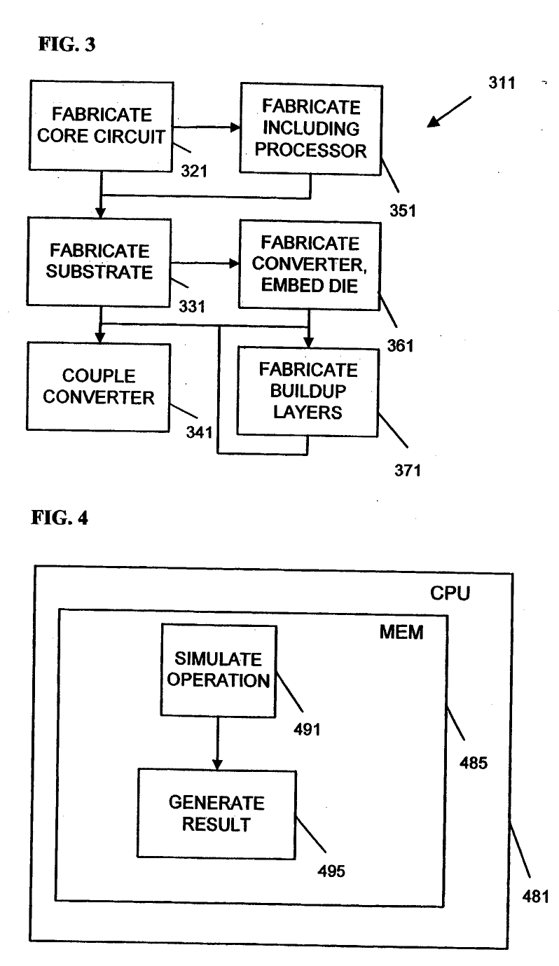

Embodiments of the invention also include a number of methods. For example, FIG. 3 is a flow chart illustrating several methods according to various embodiments of the invention. In an embodiment, a method 311 may begin with fabricating a core circuit on a first die at block 321, fabricating a substrate including one or more power converters at block 331, and coupling the power converter to the core circuit at block 341. Fabricating the core circuit on the first die at block 321 may further comprise fabricating the core circuit to include a processor at block 351.

Fabricating the substrate including the power converter(s) at block 331 may further comprise fabricating a power converter on a second die and embedding the second die in the substrate at block 361. In addition, or alternatively, fabricating the substrate including the power converter(s) at block 331 may comprise fabricating a plurality of buildup layers coupled to the substrate at block 371. As noted previously, the power converter(s) may include one or more switching devices, one or more of the buildup layers may include inductors and/or capacitors, and the active substrate may also include inductors and/or capacitors.

It should be noted that the methods described herein do not have to be executed in the order described, or in any particular order. Moreover, various activities described with respect to the methods identified herein can be executed in serial or parallel fashion.

FIG. 4 is a block diagram of an article according to various embodiments of the invention. Thus, another embodiment of the invention may include an article 481, such as a computer, a memory system, a magnetic or optical disk, some other storage device, and/or any type of electronic device or system, comprising a machine-accessible medium such as a memory 485 (e.g., a memory including an electrical, optical, or electromagnetic conductor) having associated data 491, 495 (e.g., computer program instructions), which when accessed, results in a machine performing such actions as simulating an operation of a core circuit fabricated on a die and electrically coupled to a power converter included in an active substrate and generating a human-perceivable result of simulating the operation. For such simulation activity, the core circuit may include any number of circuits, such as a processor included in a package. The result may include, for example, an analysis of power supply signal propagation through the power converter into the core circuit. In addition, the result may include an analysis of power dissipation from the core circuit through the active substrate.

Although specific embodiments have been illustrated and described herein, it should be appreciated that any arrangement calculated to achieve the same purpose may be substituted for the specific embodiments shown. This disclosure is intended to cover any and all adaptations or variations of various embodiments of the invention. It is to be understood that the above description has been made in an illustrative fashion, and not a restrictive one. Combinations of the above embodiments, and other embodiments not specifically described herein will be apparent to those of skill in the art upon reviewing the above description.

The scope of various embodiments of the invention includes any other applications in which the above structures and methods are used. Therefore, the scope of various embodiments of the invention should be determined with reference to the appended claims, along with the full range of equivalents to which such claims are entitled.

It is emphasized that the Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

What is claimed is:

1. An apparatus, comprising:
a die including a core circuit; and
an active substrate having a power converter electrically coupled to the core circuit.

2. The apparatus of claim 1, wherein the power converter operates to reduce a supply voltage to provide a reduced supply voltage to the core circuit.

3. The apparatus of claim 1, wherein the core circuit comprises: a processor.

4. The apparatus of claim 1, wherein the power converter comprises: a power switching device.

5. The apparatus of claim 1, further comprising: a plurality of buildup layers coupled to the active substrate.

6. The apparatus of claim 5, wherein one of the plurality of buildup layers further comprises:
an inductor comprising magnetic material.

7. The apparatus of claim 1, wherein the substrate further comprises:
a plurality of pins coupled to the power converter.

8. A system, comprising:
a wireless transceiver;
a die including a core circuit capable of being communicatively coupled to the wireless transceiver; and
an active substrate having a power converter electrically coupled to the core circuit.

9. The system of claim 8, wherein the active substrate further comprises:
a capacitor having a metal-insulator-metal structure.

10. The system of claim 8, wherein the active substrate is configured as a land-grid array.

11. The system of claim 8, wherein the die is embedded in the active substrate using a bump-less build-up layer process.

12. The system of claim 8, wherein a thermal coefficient of expansion associated with the die substantially matches a thermal coefficient of expansion associated with the active substrate.

13. A method, comprising:
fabricating a core circuit on a first die;
fabricating a substrate including a power converter; and
coupling the power converter to the core circuit.

14. The method of claim 13, wherein fabricating the substrate including the power converter further comprises:
fabricating a power converter on a second die; and
embedding the second die in the substrate.

15. The method of claim 13, wherein fabricating the substrate including the power converter further comprises:
fabricating a plurality of buildup layers coupled to the substrate.

16. The method of claim 15, wherein fabricating the core circuit on the first die further comprises:
fabricating the core circuit to include a processor.

17. The method of claim 16, wherein the power converter includes a switching device, wherein one of the plurality of buildup layers includes an inductor, and wherein the substrate includes a capacitor.

18. An article comprising a machine-accessible medium having associated data, wherein the data, when accessed, results in a machine performing:
simulating an operation of a core circuit fabricated on a die and electrically coupled to a power converter included in an active substrate; and
generating a human-perceivable result of the simulating.

19. The article of claim 18, wherein the core circuit is a processor included in a package.

20. The article of claim 18, wherein the result includes an analysis of power supply signal propagation through the power converter into the core circuit.

21. The article of claim 18, wherein the result includes an analysis of power dissipation from the core circuit through the active substrate.
